(19) United States
(12) Patent Application Publication
(10) Pub. No.: US 2026/0255698 A1
(43) Pub. Date: Aug. 27, 2026

(54) PHOTODETECTORS FOR A PHOTONIC CHIP

(71) Applicant: GlobalFoundries U.S. Inc., Malta, NY (US)

(72) Inventors: Ranjan Das, Leuven (BE); Bartlomiej Jan Pawlak, Leuven (BE); Judson R. Holt, Ballston Lake, NY (US)

(21) Appl. No.: 19/064,933

(22) Filed: Feb. 27, 2025

(51) Int. Cl. H10F 30/225; H10F 71/00; H10F 77/00; H10F 77/1223; H10F 77/14

(52) U.S. Cl. CPC H10F 30/225; H10F 71/1212; H10F 77/1223; H10F 77/147; H10F 77/933

(57) ABSTRACT

Structures for a photodetector and methods of forming a structure for a photodetector. The structure comprises a photodetector including a pad, a semiconductor layer, a first doped region in the pad, and a second doped region in the pad. The semiconductor layer adjoins the pad along an interface, and the first and doped regions are positioned adjacent to the interface.

### BACKGROUND

This disclosure relates to photonic chips and, more specifically, to structures for a photodetector and methods of forming such structures.

Photonic chips are used in many applications and systems including, but not limited to, data communication systems and data computation systems. A photonic chip includes a photonic integrated circuit comprised of photonic components, such as modulators, polarizers, and couplers, that are used to manipulate light received from a light source, such as an optical fiber or a laser. A photodetector may be employed in the photonic integrated circuit to convert light, which may be modulated as an optical signal, into an electrical signal.

Photodetectors used in silicon photonic applications may include a layer of germanium that is epitaxally grown on a silicon pad. Germanium may be used as a light-absorbing material because of its strong absorbance of infrared light and its ease of integration into standard silicon complementary metal-oxide semiconductor processing. However, defects along the germanium/silicon interface arising from lattice mismatch may function to unwantedly increase dark current flow.

Improved structures for a photodetector and methods of forming such structures are needed.

### SUMMARY

In an embodiment of the invention, a structure comprises a photodetector including a pad, a semiconductor layer, a first doped region in the pad, and a second doped region in the pad. The semiconductor layer adjoins the pad along an interface, and the first doped region and the second doped region are positioned adjacent to the interface.

In an embodiment of the invention, a method comprises forming a photodetector including a pad, a semiconductor layer, a first doped region in the pad, and a second doped region in the pad. The semiconductor layer adjoins the pad along an interface, and the first doped region and the second doped region are positioned adjacent to the interface.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 1A is a cross-sectional view taken generally along line 1A-1A in FIG. 1.

FIG. 2 is a top view of the structure at a fabrication stage of the processing method subsequent to FIGS. 1, 1A.

FIG. 2A is a cross-sectional view taken generally along line 2A-2A in FIG. 2.

FIG. 3 is a cross-sectional view of the structure at a fabrication stage of the processing method subsequent to FIGS. 2, 2A.

FIG. 4 is a cross-sectional view of a structure in accordance with alternative embodiments of the invention.

FIG. 5 is a cross-sectional view of a structure in accordance with alternative embodiments of the invention.

FIG. 6 is a cross-sectional view of a structure in accordance with alternative embodiments of the invention.

FIG. 7 is a cross-sectional view of a structure in accordance with alternative embodiments of the invention.

FIG. 8 is a cross-sectional view of a structure in accordance with alternative embodiments of the invention.

FIG. 9 is a cross-sectional view of a structure in accordance with alternative embodiments of the invention.

### DETAILED DESCRIPTION

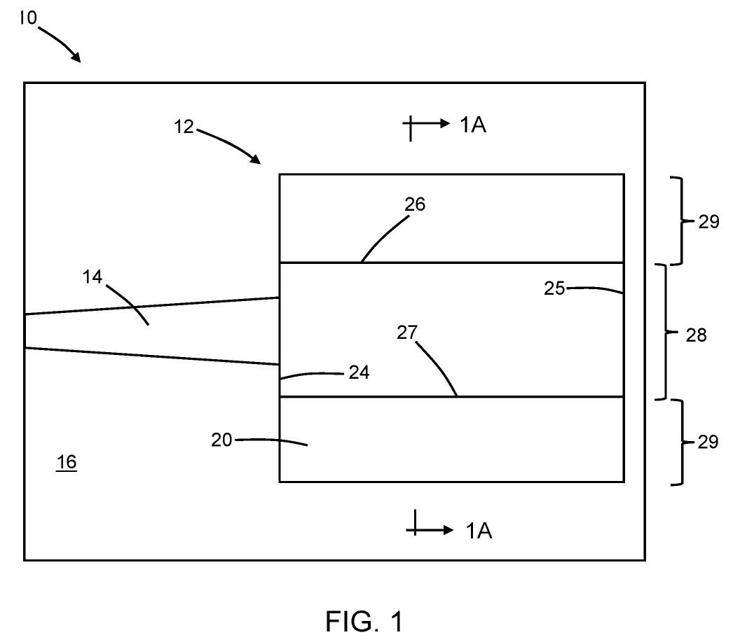

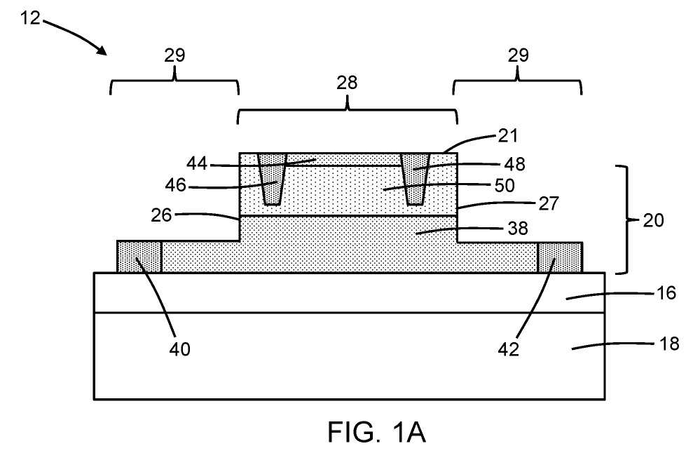

With reference to FIGS. 1, 1A and in accordance with embodiments of the invention, a structure 10 for a photonic chip includes a photodetector 12 and a waveguide core 14 that is coupled to the photodetector 12. The photodetector 12 and the waveguide core 14 are positioned on, and above, a dielectric layer 16 and a semiconductor substrate 18. In an embodiment, the dielectric layer 16 may be comprised of a dielectric material, such as an oxide of silicon (e.g., silicon dioxide), and the semiconductor substrate 18 may be comprised of a semiconductor material, such as single-crystal silicon. In an embodiment, the dielectric layer 16 may be a buried oxide layer of a silicon-on-insulator substrate. The dielectric layer 16 may provide low-index cladding that separates the photodetector 12 and the waveguide core 14 from the semiconductor substrate 18.

The photodetector 12 includes a pad 20 that is positioned on the dielectric layer 16. The pad 20 includes a section 28 having a side edge 24, a side edge 25 opposite from the side edge 24, a side edge 26, and a side edge 27 opposite from the side edge 26. The side edges 24, 25, 26, 27 surround a perimeter of the section 28 of the pad 20. The pad 20 includes a slab layer 29 representing a thinner section that extends outwardly from the side edges 26, 27 of the section 28.

The waveguide core 14 may include a tapered section that adjoins the side edge 24 of the section 28 of the pad 20. The tapered section of the waveguide core 14 may have a width dimension that increases with decreasing distance from the side edge 24. In an embodiment, the width dimension of the tapered section of the waveguide core 14 may increase linearly with decreasing distance from the side edge 24. In an alternative embodiment, the width dimension of the tapered section of the waveguide core 14 may vary based on a non-linear function, such as a quadratic function, a cubic function, a parabolic function, a sine function, a cosine function, a Bezier function, or an exponential function. In an embodiment, the tapered section of the waveguide core 14 may include a single stage of tapering characterized by a taper angle. In an alternative embodiment, the tapered section of the waveguide core 14 may taper in multiple stages each characterized by a different taper angle.

In an embodiment, the waveguide core 14 and the pad 20 of the photodetector 12 may be comprised of a material having a refractive index that is greater than the refractive index of silicon dioxide. In an embodiment, the waveguide core 14 and the pad 20 of the photodetector 12 may be comprised of a semiconductor material. In an embodiment, the waveguide core 14 and the pad 20 of the photodetector 12 may be comprised of single-crystal silicon. The waveguide core 14 and the pad 20 of the photodetector 12 may be formed by patterning a layer comprised of their constituent material with lithography and etching processes. In an embodiment, the waveguide core 14 and the pad 20 of the photodetector 12 may be formed by patterning the semiconductor material, which may be single-crystal silicon, of the device layer of a silicon-on-insulator substrate.

The photodetector 12 may include a doped region 38 that is arranged in the section 28 and the slab layer 29 of the pad 20. An undoped upper portion of the section 28 of the pad 20 is arranged between the doped region 38 and the top surface 21 of the pad 20. The upper portion of the section 28 of the pad 20 may comprise an intrinsic semiconductor material. In an embodiment, the upper portion of the section 28 of the pad 20 may comprise intrinsic silicon.

The doped region 38 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 38. The implantation mask may be stripped after forming the doped region 38. In an embodiment, the semiconductor material of the doped region 42 may contain an n-type dopant, such as phosphorus, that provides n-type electrical conductivity.

The photodetector 12 includes a region 50 arranged between the doped region 38 and the top surface 21 of the pad 20. The region 50 is comprised of semiconductor material of the pad 20 that is intrinsic and undoped.

The photodetector 12 may include doped regions 40, 42 that are arranged at the peripheral edges of the slab layer 29 of the pad 20. The doped regions 40, 42, which may be characterized by the same conductivity type as the doped region 38 but at a higher dopant concentration, may extend through the entire thickness of the slab layer 29 to the underlying dielectric layer 16. The doped regions 40, 42 may be formed by, for example, ion implantation with an implantation mask having openings that determine the implanted areas of the slab layer 29. The implantation mask may include a layer of photoresist applied by a spin-coating process, pre-baked, exposed to light projected through a photomask, baked after exposure, and developed with a chemical developer to define openings over the areas of the slab layer 29 to be implanted. The implantation conditions, such as ion species, dose, and kinetic energy, may be selected to tune the electrical and physical characteristics of the doped regions 40, 42. The implantation mask may be stripped after forming the doped regions 40, 42. In an embodiment, the semiconductor material of the doped regions 40, 42 may contain an n-type dopant, such as phosphorus, that provides n-type electrical conductivity.

The photodetector 12 may include a doped region 44 that is arranged in the pad 20 adjacent to the top surface 21. In an embodiment, the doped region 44 may adjoin the top surface 21 of the pad 20. The doped region 44 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 44. The implantation mask may be stripped after forming the doped region 42. In an embodiment, the semiconductor material of the doped region 44 may contain a p-type dopant, such as boron, that provides p-type electrical conductivity.

The photodetector 12 may include a doped region 46 and a doped region 48 that are arranged in the pad 20 adjacent to the top surface 21. In an embodiment, uppermost portions of the doped regions 46, 48 may adjoin the top surface 21 of the pad 20. The doped regions 46, 48 may extend from the top surface 21 of the pad 20 toward the doped region 38. Lowermost portions of the doped regions 46, 48, which are located at the greatest distance from the top surface 21, are spaced above the doped region 38.

The doped region 44 is arranged in a lateral direction between the doped region 46 and the doped region 48. In an embodiment, the doped regions 46, 48 may have the same conductivity type. In an embodiment, the doped regions 46, 48 may have the same conductivity type, and the conductivity type of the doped regions 46, 48 may be opposite to the conductivity type of the doped region 44. In an embodiment, the doped region 44 may extend in a lateral direction from the doped region 46 to the doped region 48. In an embodiment, the doped region 44 may extend in a vertical direction to a shallower depth in the pad 20 than the doped regions 46, 48.

The doped regions 46, 48 may be formed by, for example, ion implantation with an implantation mask having openings that determine the implanted area of the pad 20. The implantation mask may include a layer of photoresist applied by a spin-coating process, pre-baked, exposed to light projected through a photomask, baked after exposure, and developed with a chemical developer to define openings over the areas of the pad 20 to be implanted. The implantation conditions, such as ion species, dose, and kinetic energy, may be selected to tune the electrical and physical characteristics of the doped regions 46, 48. The implantation mask may be stripped after forming the doped regions 46, 48. In an embodiment, the semiconductor material of the doped regions 46, 48 may contain an n-type dopant, such as phosphorus, that provides n-type electrical conductivity.

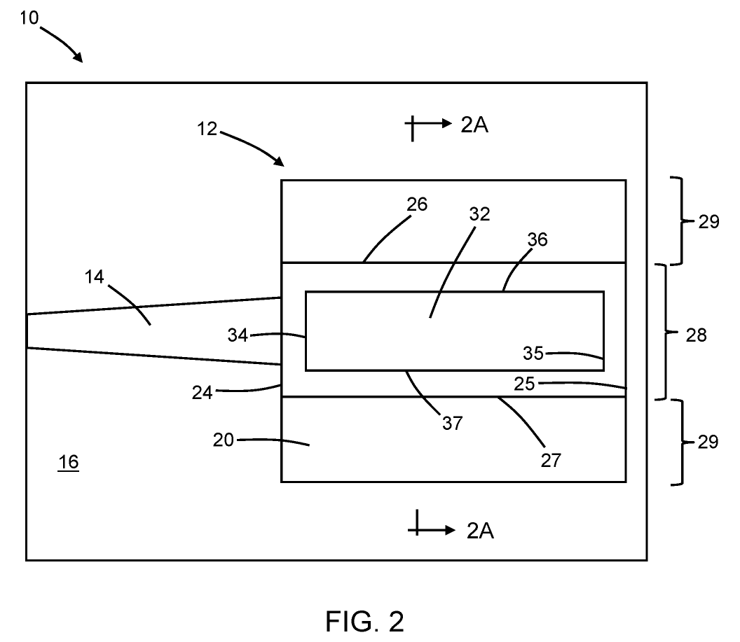

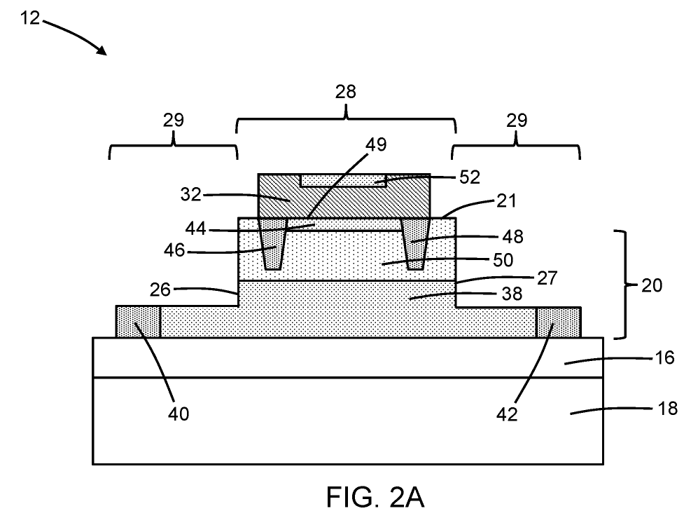

With reference to FIGS. 2, 2A in which like reference numerals refer to like features in FIGS. 1, 1A and at a subsequent fabrication stage, the photodetector 12 further includes a semiconductor layer 32 representing a light-absorbing portion that overlies the section 28 of the pad 20 at the top surface 21. The semiconductor layer 32 is arranged on the pad 20 with an inward spacing from the outer perimeter of the section 28 of the pad 20. The semiconductor layer 32 may have a perimeter surrounded by a sidewall 34, a sidewall 35 opposite from the sidewall 34, a sidewall 36, and a sidewall 37 opposite from the sidewall 36. The sidewall 34 is positioned adjacent to the side edge 24 of the section 28 of the pad 20, the sidewall 35 is positioned adjacent to the side edge 25 of the section 28 of the pad 20, the sidewall 36 is positioned adjacent to the side edge 26 of the section 28 of the pad 20, and the sidewall 37 is positioned adjacent to the side edge 27 of the section 28 of the pad 20.

The semiconductor layer 32 of the photodetector 12 may be comprised of a light-absorbing material that is configured to absorb light of a given wavelength, such as a wavelength within an infrared wavelength band of the electromagnetic spectrum, and to generate charge carriers from photons of the absorbed light by photoelectric conversion. In an embodiment, the semiconductor layer 32 may be comprised of a different material from the waveguide core 14 and/or the pad 20. In an embodiment, the semiconductor layer 32 may be comprised of a material having a composition that includes germanium. In an embodiment, the semiconductor layer 32 may be comprised of germanium that is undoped and intrinsic. In an alternative embodiment, the semiconductor layer 32 may be comprised of germanium that is doped with a p-type dopant to provide p-type electrical conductivity.

The semiconductor layer 32 may be formed by an epitaxial growth process. In an embodiment, the semiconductor layer 32 may be positioned fully above the top surface 21. In an embodiment, the semiconductor layer 32 may be epitaxially grown from the top surface 21 of the pad 20 and then patterned by lithography and etching processes.

The semiconductor layer 32 adjoins the pad 20 along an interface 49 across which the type of semiconductor material changes from the semiconductor material of the pad 20 to the semiconductor material of the semiconductor layer 32. The doped region 46 is positioned adjacent to the sidewall 36 of the semiconductor layer 32, and the doped region 48 is positioned adjacent to the sidewall 37 of the semiconductor layer 32. In an embodiment, the doped region 46 may be laterally offset from the sidewall 36, and the doped region 48 may be laterally offset from the sidewall 37. The semiconductor layer 32 overlaps with the doped region 44, which is arranged in a lateral direction between the doped region 46 and the doped region 48. In an embodiment, the semiconductor layer 32 may fully overlap with the doped regions 46, 48. In an embodiment, the semiconductor layer 32 may partially overlap with the doped regions 46, 48.

A doped region 52 may be formed in an upper portion of the semiconductor layer 32. The doped region 52 is laterally offset from the sidewalls 36, 37 of the semiconductor layer 32. The doped region 52 may be formed by, for example, ion implantation with an implantation mask with an opening that determines an implanted area of the semiconductor layer 32. The implantation mask may include a layer of photoresist applied by a spin-coating process, pre-baked, exposed to light projected through a photomask, baked after exposure, and developed with a chemical developer to define the opening over the area of the semiconductor layer 32 to be implanted. The implantation conditions, such as ion species, dose, and kinetic energy, may be selected to tune the electrical and physical characteristics of the doped region 52. The implantation mask may be stripped after forming the doped region 52. In an embodiment, the semiconductor material of the doped region 52 may contain a p-type dopant, such as boron, that provides p-type electrical conductivity.

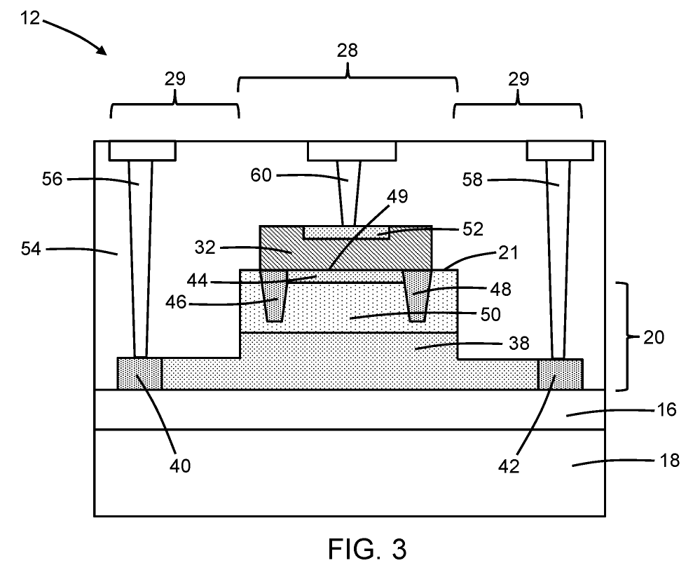

With reference to FIG. 3 in which like reference numerals refer to like features in FIG. 2, 2A and at a subsequent fabrication stage, a dielectric layer 54 may be formed over the photodetector 12 and waveguide core 14. The dielectric layer 54 may be comprised of a dielectric material, such as an oxide of silicon (e.g., silicon dioxide), having a refractive index that is less than the refractive index of the material constituting the waveguide core 14. Interconnects 56, 58, 60 may be formed that are respectively coupled to the doped regions 40, 42 and the doped region 52. The interconnects 56, 58, 60 may be used to bias the photodetector 12 and to collect charge carriers during operation of the photodetector 12.

In use, light propagates in the waveguide core 14 toward the photodetector 12 and light is coupled from the waveguide core 14 to the semiconductor layer 32 of the photodetector 12. In an embodiment, the light received by the photodetector 12 may be laser light that is modulated as an optical signal. The semiconductor layer 32 of the photodetector 12 absorbs photons of the light and converts the absorbed photons into charge carriers by photoelectric conversion. The biasing of the doped regions 40, 42 and doped region 52 causes the charge carriers to be collected and output to provide, as a function of time, a measurable photocurrent.

The photodetector 12 may be characterized as a vertical avalanche photodetector with a separate absorption, charge, and multiplication (SACM) design. The semiconductor layer 32 represents an absorption layer of the vertical avalanche photodetector, the doped region 44 represents a charge sheet of the vertical avalanche photodetector, and the intrinsic semiconductor material of the region 50 represents a multiplication layer of the vertical avalanche photodetector. The doped region 38, which is coupled by the doped regions 40, 42 to the interconnects 56, 58, may represent a cathode of the vertical avalanche photodetector, and the doped region 52 may represent an anode of the vertical avalanche photodetector.

The doped regions 46, 48 of the photodetector 12 may function to suppress dark current flowing along the interface 49 between the semiconductor layer 32 and the pad 20. The doped regions 46, 48 may manipulate the electric field at the interface 49 to provide the dark current suppression. The doped regions 46, 48 lack connections to interconnects and, for that reason, are electrically floating in the operating photodetector 12.

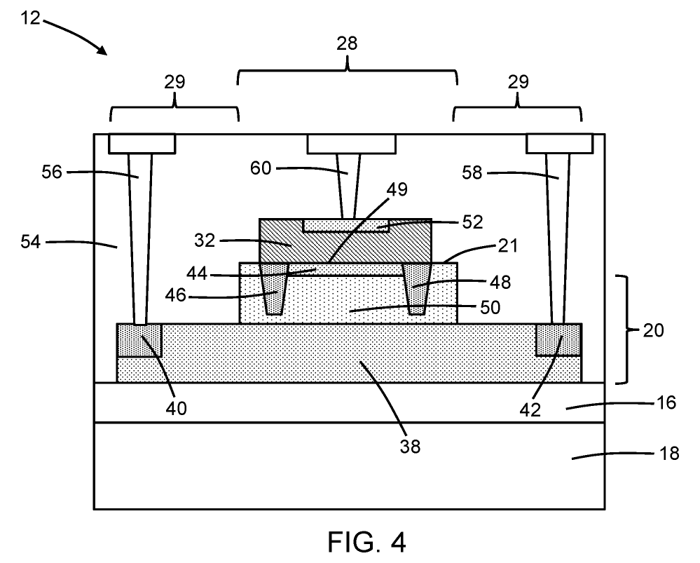

With reference to FIG. 4 and in accordance with alternative embodiments, the slab layer 29 may be thickened such that the portion of the pad 22 that includes the doped region 38 and doped regions 40, 42 has a uniform thickness. The doped regions 40, 42 may be spaced above the interface between the pad 20 and the dielectric layer 16.

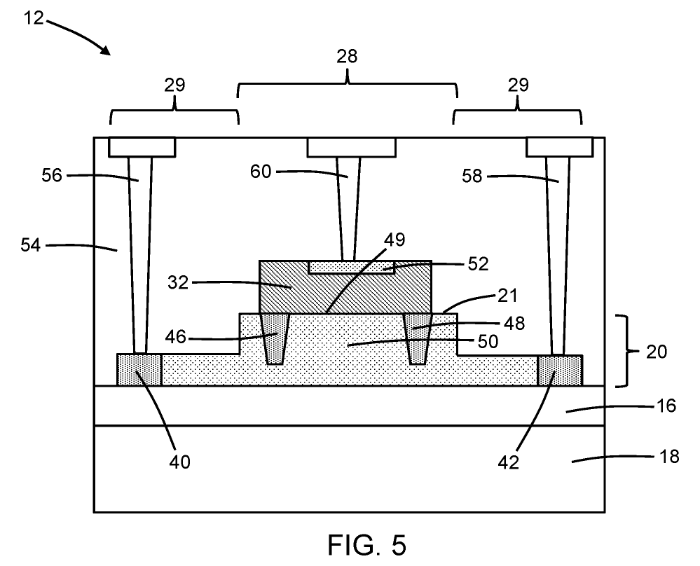

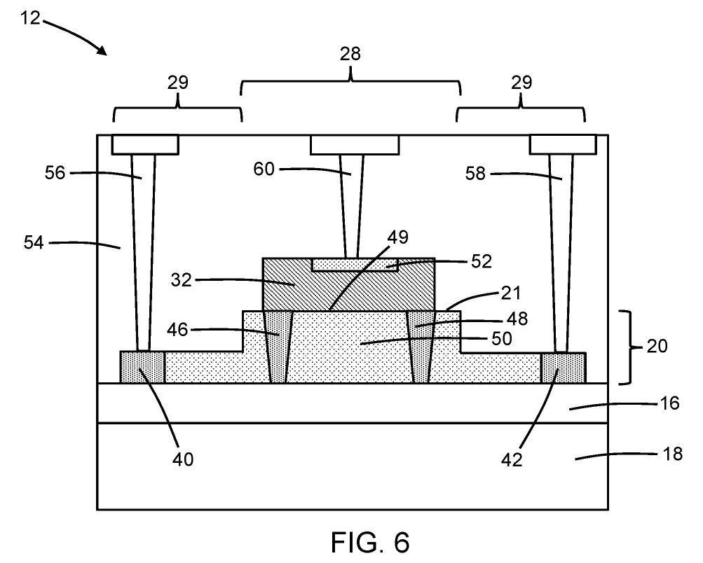

With reference to FIGS. 5 and 6 and in accordance with alternative embodiments, the doped region 44 may be eliminated such that the photodetector 12 is structured as a vertical avalanche photodetector that lacks a charge sheet. The doped region 38 may also be eliminated such that the section 28 of the pad 20 only includes the region 50 of intrinsic semiconductor material. In an embodiment as shown in FIG. 5, the doped regions 46, 48 may extend partially through the pad 20. In an embodiment as shown in FIG. 6, the doped regions 46, 48 may extend fully through the pad 20 to the dielectric layer 16.

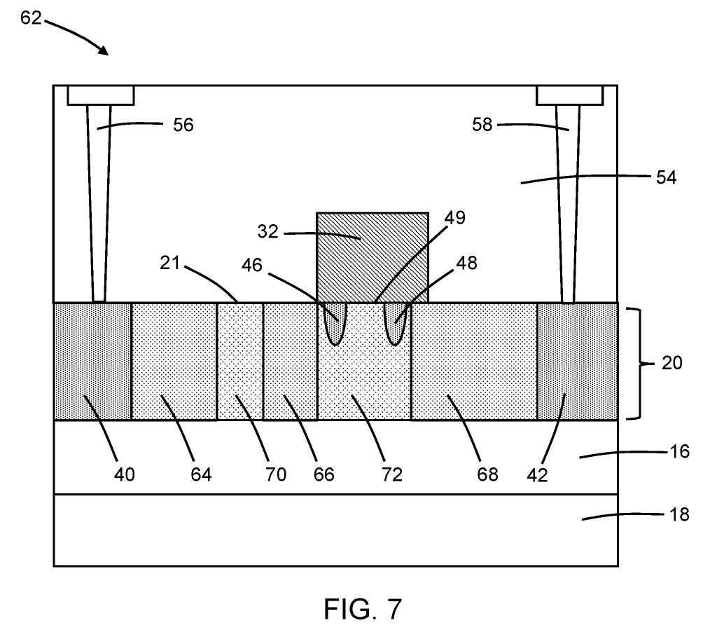

With reference to FIG. 7 and in accordance with alternative embodiments, a photodetector 62 includes a pad 20 having a doped region 64, a doped region 66, a doped region 68, and regions 70, 72. In an embodiment, the doped region 64 may be doped with an n-type dopant to provide n-type electrical conductivity, the doped region 40 may be heavily-doped with the n-type dopant, the doped regions 66, 68 may be doped with a p-type dopant to provide p-type electrical conductivity, the doped region 42 may be heavily-doped with the p-type dopant, and the regions 70, 72 may be comprised of intrinsic semiconductor material, such as intrinsic silicon. The doped regions 66, 68 may be formed by an ion implantation process using a suitable implantation mask, and the doped region 64 may be formed by an ion implantation process using a suitable implantation mask.

The doped region 64 is arranged in a lateral direction between the doped region 40 and the region 70 of intrinsic semiconductor material. The doped region 66 is arranged in a lateral direction between the region 70 of intrinsic semiconductor material and the region 72 of intrinsic semiconductor material. The doped region 68 is arranged in a lateral direction between the doped region 42 and the region 72 of intrinsic semiconductor material.

The semiconductor layer 32 is arranged fully above the top surface of the pad 20 and adjoins the pad 20 along the interface 49 between the pad 20 and the semiconductor layer 32. The doped regions 46, 48, which are positioned in the region 72 along the interface 49, may be fully overlapped by the semiconductor layer 32.

The photodetector 62 may be characterized as a lateral avalanche photodetector with a separate absorption, charge, and multiplication (SACM) design. The semiconductor layer 32 represents an absorption layer of the lateral avalanche photodetector, the doped region 66 represents a charge sheet of the lateral avalanche photodetector, and the intrinsic semiconductor material of the region 70 of the pad 20 between the doped region 64 and the doped region 66 represents a multiplication layer of the lateral avalanche photodetector. The charge sheet and the multiplication layer are laterally arranged inside the pad 20.

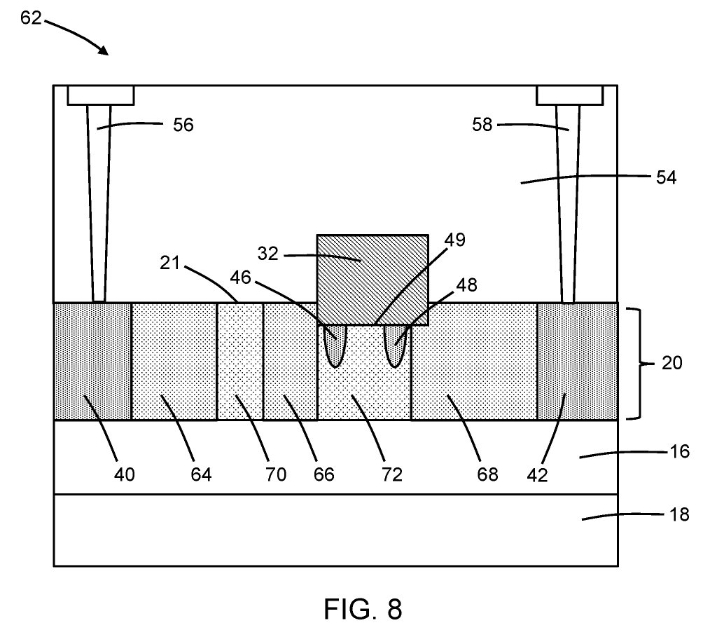

With reference to FIG. 8 and in accordance with alternative embodiments, the semiconductor layer 32 of the lateral avalanche photodetector may include an upper portion that is arranged above the top surface 21 of the pad 20 and a lower portion that is arranged below the top surface 21 of the pad 20. The doped regions 46, 48, which are positioned in the region 72 along the interface 49 between the pad 20 and the semiconductor layer 32, may be fully overlapped by the semiconductor layer 32.

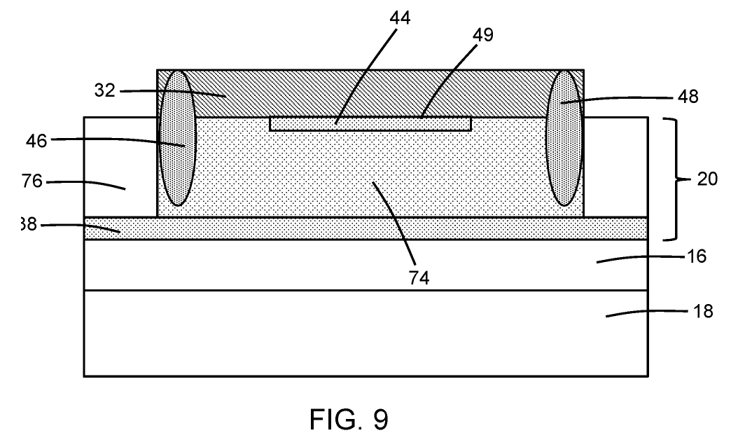

With reference to FIG. 9 and in accordance with alternative embodiments, the pad 20 of photodetector 12 may include a region 74 of epitaxially-grown intrinsic semiconductor material, such as intrinsic silicon, that overlies the doped region 38. The region 74 is arranged inside an opening in a dielectric layer 76. The semiconductor layer 32 adjoins the pad 20 along the interface 49.

The doped regions 46, 48 are positioned along the interface 49. In an embodiment, the doped region 46 includes a lower portion in the pad 20 and an upper portion in the semiconductor layer 32, and the doped region 48 includes a lower portion in the pad 20 and an upper portion in the semiconductor layer 32. The lower portions of the doped regions 46, 48 may be overlapped by the semiconductor layer 32

The doped region 44 may extend over a portion of the width dimension of the region 72. In an alternative embodiment, the doped region 44 may extend over the full width dimension of the region 72. In an alternative embodiment, a cap layer comprised of, for example, silicon may be applied that conformally coats the semiconductor layer 32.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a photonic chip, the structure comprising:
a photodetector including a pad, a semiconductor layer, a first doped region in the pad, and a second doped region in the pad, the semiconductor layer adjoining the pad along an interface, and the first doped region and the second doped region adjacent to the interface.

2. The structure of claim 1 wherein the pad has a side edge, and further comprising:
a waveguide core including a section adjoined to the side edge of the pad.

3. The structure of claim 1 wherein the first doped region and the second doped region adjoin the interface.

4. The structure of claim 3 wherein the photodetector includes a third doped region in the pad, the first doped region and the second doped region have a first conductivity type, the third doped region is positioned laterally between the first doped region and the second doped region, and the third doped region has a second conductivity type opposite to the first conductivity type.

5. The structure of claim 4 wherein the third doped region extends to a shallower depth in the pad than the first doped region and the second doped region.

6. The structure of claim 4 wherein the third doped region extends in a lateral direction from the first doped region to the second doped region.

7. The structure of claim 4 wherein the first conductivity type is n-type, and the second conductivity type is p-type.

8. The structure of claim 3 wherein the semiconductor layer overlaps with the first doped region and the second doped region.

9. The structure of claim 3 wherein the semiconductor layer fully overlaps with the first doped region and the second doped region.

10. The structure of claim 1 wherein the semiconductor layer overlaps with the first doped region and the second doped region.

11. The structure of claim 1 wherein the pad comprises an intrinsic semiconductor material region.

12. The structure of claim 11 wherein the semiconductor layer adjoins the intrinsic semiconductor material region.

13. The structure of claim 11 wherein the photodetector includes a third doped region in the pad, and the third doped region is arranged between the intrinsic semiconductor material region and the semiconductor layer.

14. The structure of claim 1 wherein the first doped region includes a first portion in the pad and a second portion in the semiconductor layer, and the second doped region includes a first portion in the pad and a second portion in the semiconductor layer.

15. The structure of claim 1 wherein the first doped region and the second doped region extend from the interface partially through the pad.

16. The structure of claim 1 further comprising:
a dielectric layer,
wherein the pad is positioned on the dielectric layer, and the first doped region and the second doped region extend from the interface fully through the pad to the dielectric layer.

17. The structure of claim 1 wherein the semiconductor layer comprises an intrinsic semiconductor material region and a third doped region, the intrinsic semiconductor material region is arranged between the third doped region and the interface, and the first doped region and the second doped region are arranged between the third doped region and the interface.

18. The structure of claim 17 wherein the pad includes a fourth doped region, and the intrinsic semiconductor material region is arranged between the third doped region and the fourth doped region.

19. The structure of claim 18 wherein the first doped region, the second doped region, and the third doped region have a first conductivity type, and the fourth doped region has a second conductivity type opposite to the first conductivity type.

20. A method of forming a structure for a photonic chip, the method comprising:
forming a photodetector including a pad, a semiconductor layer, a first doped region in the pad, and a second doped region in the pad, wherein the semiconductor layer adjoins the pad along an interface, and the first doped region and the second doped region are positioned adjacent to the interface.
